(19) United States
(12) Patent Application Publication
(10) Pub. No.: US 2026/0293568 A1
(43) Pub. Date: Sep. 24, 2026

(54) MOVABLE VOLATILE ORGANIC COMPOUNDS (VOC) ROTOR ANTI-SKID CHAIN IMPLEMENT

(71) Applicants: TSMC CHINA COMPANY LIMITED, Shanghai (CN); TAIWAN SEMICONDUCTOR MANUFACTURING COMPANY, LTD., Hsinchu (TW)

(72) Inventors: Xingkang WANG, Shanghai City (CN); Weiwei XIA, Shanghai City (CN); Cheng-Tao HUANG, Tainan City (TW); Aijun ZHU, Shanghai City (CN)

(73) Assignees: TSMC CHINA COMPANY LIMITED, Shanghai (CN); TAIWAN SEMICONDUCTOR MANUFACTURING COMPANY, LTD., Hsinchu (TW)

(21) Appl. No.: 19/178,449

(22) Filed: Apr. 14, 2025

(30) Foreign Application Priority Data
Mar. 19, 2025 (CN) 202520494152.5

(51) Int. Cl. H01L 21/67; F16H 7/06; F16H 7/08; F16H 7/12

(52) U.S. Cl. CPC H10P 72/0402; F16H 7/06; F16H 7/1263; F16H 2007/087; F16H 2007/0891; F16H 2007/0897

(57) ABSTRACT

A method includes performing a volatile organic compound (VOC) exhaust process using a VOC exhaust system, the VOC exhaust system comprises a concentrator wheel, a rotor, a traction chain mechanically coupling the concentrator wheel and the rotor, and a chain adjustment tool having a gear coupled to a bottom side of the traction chain, wherein the traction chain comprises a first segment on one side of the gear and a second segment on another side of the gear; performing a cleaning process to the VOC exhaust system; and moving the gear of the chain adjustment tool along a horizontal direction until a bottom end of the first segment and a bottom end of the second segment are substantially at a same level.

### PRIORITY CLAIM AND CROSS-REFERENCE

The present application claims priority to China Application Serial Number 202520494152.5, filed Mar. 19, 2025, which is herein incorporated by reference.

### BACKGROUND

A large variety of semiconductor processes are utilized in fabricating integrated circuits. Such processes can include thin-film deposition processes, etching processes, annealing processes, lithography processes, and many other types of processes. Semiconductor processes often generate exhaust fluids. These exhaust fluids sometimes include high concentrations of volatile organic compound (VOC). Volatile organic compounds are harmful if released into the atmosphere.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a block diagram of a VOC exhaust system, according to some embodiments of the present disclosure.

FIG. 2 is a schematic view of a VOC exhaust system, according to some embodiments of the present disclosure.

FIGS. 3A, 3B, and 3C are schematic views of a chain adjustment tool of a VOC exhaust system, according to some embodiments of the present disclosure.

FIG. 4 is a method of operating a VOC exhaust system in accordance with some embodiments.

FIGS. 5 to 9 are schematic views of a VOC exhaust system at various stages of operating a VOC exhaust system accordance with some embodiments.

FIG. 10 is a schematic view of a VOC exhaust system, according to some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

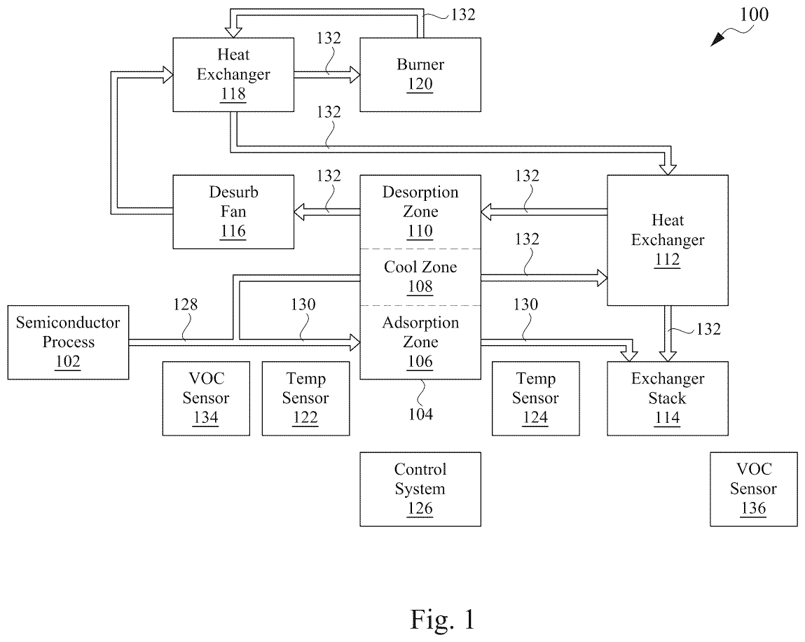

FIG. 1 is a block diagram of a VOC exhaust system 100, according to one embodiment. The VOC exhaust system 100 includes a concentrator wheel 104. The VOC concentrator wheel 104 includes an adsorption zone 106, a cooling zone 108, and a desorption zone 110. The VOC exhaust system 100 further includes a heat exchanger 112, an exhaust stack 114, a desorption fan 116, a heat exchanger 118, a burner 120, temperature sensors 122 and 124, and a control system 126.

A semiconductor process 102 generates exhaust fluid 128. Examples of the semiconductor process 102 can include a thin-film deposition process, an etching process, a doping process, an annealing process, or other thin-film deposition processes. Furthermore, the scope of the present disclosure is not limited to exhaust fluids generated by semiconductor processes. Other processes such as thin-film transistor processes or other processes for forming thin-film electronic devices such as LCD screen devices and other types of devices can result in the exhaust fluid 128 including VOCs. The exhaust fluid 128 may include a high concentration of VOCs. It is beneficial to remove the VOCs from the exhaust fluid 128 before the exhaust fluid is released into the atmosphere. The VOC exhaust system 100 removes VOCs from the exhaust fluid 128.

The exhaust fluid 128 is passed to the VOC concentrator wheel 104. In one embodiment, the VOC concentrator wheel 104 has a shape of a large wheel with a diameter between 3 m and 5 m, though other diameters can be utilized without departing from the scope of the present disclosure.

The VOC concentrator wheel 104 includes an adsorption zone 106, a cooling zone 108, and a desorption zone 110. More properly, it may be stated that the VOC concentrator wheel 104 rotates through an adsorption zone 106, a cooling zone 108, and a desorption zone 110. This is because the VOC concentrator wheel 104 slowly rotates. The adsorption zone 106, the cooling zone 108, and the desorption zone 110 remain stationary. The VOC concentrator wheel 104 rotates through each of the zones. In particular, the VOC concentrator wheel 104 rotates from the adsorption zone 106 to the desorption zone 110, from the desorption zone 110 to the cooling zone 108, and from the cooling zone 108 back to the adsorption zone 106.

In one embodiment, the VOC concentrator wheel 104 includes a calcinated ceramic honeycomb substrate. The honeycomb substrate may include an inorganic binder. Aluminosilicate hydrate, also called zeolite, is embedded into the ceramic honeycomb substrate. The VOC concentrator wheel 104 with this structure and material is able to adsorb VOCs from the exhaust gas at low temperature and to desorb VOCs into the exhaust gas at high temperatures. Other materials and structures can be utilized for the VOC concentrator wheel 104 without departing from the scope of the present disclosure.

When the exhaust fluid 128 is passed from the semiconductor process 102 to the VOC concentrator wheel 104, a first portion 130 of the exhaust fluid 128 passes into the adsorption zone 106. A second portion 132 of the exhaust fluid 128 passes into the cooling zone 108 of the VOC concentrator wheel 104.

When the first portion 130 of the exhaust fluid 128 passes through the adsorption zone 106, VOCs are adsorbed onto the VOC concentrator wheel 104. The first portion 130 of the exhaust fluid 128 includes a high concentration of VOCs before passing through the adsorption zone 106 of the VOC concentrator wheel 104. After the first portion 130 of the exhaust fluid 128 passes through the adsorption zone 106 of the VOC concentrator wheel 104, the VOCs have been removed from the first portion 130 of the exhaust fluid 128. In particular, the VOCs from the first portion 130 of the exhaust fluid 128 are adsorbed onto that portion of the VOC concentrator wheel 104 passing through the adsorption zone 106.

The first portion 130 of the exhaust fluid 128 passes from the VOC concentrator wheel 104 to the exhaust stack 114. The exhaust stack 114 passes the first portion 130 exhaust fluid 128 into the atmosphere. Because the VOC concentrator wheel 104 has adsorbed the VOCs from the first portion 130 of the exhaust fluid 128, the first portion of the exhaust fluid 128 is purified when it enters the atmosphere via the exhaust stack 114.

When the second portion 132 of the exhaust fluid 128 passes through the cooling zone 108, very little of the VOCs are adsorbed from the second portion 132 of the exhaust fluid 128 onto the VOC concentrator wheel 104. This is because that portion of the VOC concentrator wheel 104 is relatively hot, for reasons I will be described further below. Because the VOC concentrator wheel 104 is at an elevated temperature, the portion of the VOC concentrator wheel 104 does not adsorb many VOCs from the second portion 132 of the exhaust fluid 128. While passing through the cooling zone 108, the temperature of the portion of the VOC concentrator wheel 104 passing through the cooling zone 108 gradually cools off. The portion of the VOC concentrator wheel 104 passing from the cooling zone 108 to the adsorption zone 106 is sufficiently cool to adsorb VOCs from the first portion of the exhaust fluid 128 in the adsorption zone 106.

The second portion 132 of the exhaust fluid 128 passes from the cooling zone 108 to the heat exchanger 112. The heat exchanger 112 heats the second portion 132 of the exhaust fluid 128 to a temperature between 190° C. and 230° C. As will be described in more detail below, the heated second portion 132 of the exhaust fluid 128 will enable the VOC concentrator wheel 104 to desorb VOCs into the heated second portion 132 of the exhaust fluid 128. The heat exchanger 112 may heat the second portion 132 of the exhaust fluid 128 to temperatures other than those described above without departing from the scope of the present disclosure.

In one embodiment, the heat exchanger 112 is replaced by a different type of heater. Any suitable heater can be utilized to heat The second portion 132 of the exhaust fluid 128 to a temperature at which the VOC concentrator wheel 104 can desorb VOCs into the second portion 132 of the exhaust fluid 128.

The second portion 132 of the exhaust fluid 128 passes from the heat exchanger 112 to the desorption zone 110 of the VOC concentrator wheel 104. Because the second portion 132 of the exhaust fluid 128 is at an elevated temperature as described above, the VOC concentrator wheel 104 desorbs VOCs from the VOC concentrator wheel 104 into the second portion 132 of the exhaust fluid 128. The result is that VOCs that were adsorbed from the first portion 130 of the exhaust fluid 128 are desorbed onto the second portion 132 of the exhaust fluid 128.

The rotation of the VOC concentrator wheel 104 enables the continuous removal of VOCs from the exhaust fluid 128 without the need to replace the VOC concentrator wheel 104. After adsorbing VOCs from the first portion 130 of the exhaust fluid 128 at the adsorption zone 106, the rotation of the VOC concentrator wheel 104 causes the VOC laden portion of the VOC concentrator wheel 104 to rotate to the desorption zone 110. At the desorption zone 110, the VOC laden portion of the VOC concentrator wheel 104 desorbs VOCs into the second portion 132 of the exhaust fluid 128. The VOC concentrator wheel 104 at the desorption zone 110 is heated by the heated second portion 132 of the exhaust fluid 128. The portion of the VOC concentrator wheel 104 leaving the desorption zone 110 is no longer laden with VOCs because the VOCs have been desorbed onto the second portion 132 of the exhaust fluid 128. The heating portion of the VOC concentrator wheel 104 cools off in the cooling zone 108 and returns to the adsorption zone 106 ready to adsorb more VOCs from the first portion 130 of the exhaust fluid 128. In this way, the VOC concentrator wheel 104 can operate continuously.

In one example, the VOC concentrator wheel 104 rotates with a rotational speed between 2 rotations per hour (rph) and 8 rph. The VOC concentrator wheel 104 can rotate at other speeds than these without departing from the scope of the present disclosure.

The desorption fan 116 takes part in the desorption process. In particular, the desorption fan 116 sucks the heated second portion 132 of the exhaust fluid 128 through the desorption zone 110 of the VOC concentrator wheel 104. Thus, the rotational speed of the desorption fan 116 affects the flow rate of the second portion 132 of the exhaust fluid 128 through the VOC concentrator wheel 104 at the desorption zone 110. Accordingly, the rotational speed of the desorption fan 116 can affect the overall efficiency of the VOC exhaust system 100, as will be described in further detail below. The desorption fan 116 includes control circuitry that enables the speed of the desorption fan 116 to be adjusted automatically by the control system 126, as will be described in further detail below.

The second portion 132 of the exhaust fluid 128 passes from the desorption fan 116 to the heat exchanger 118. The heat exchanger 118 heats the second portion 132 of the exhaust fluid 128.

The second portion 132 of the exhaust fluid 128 passes from the heat exchanger 118 to the burner 120. The burner 120 removes VOCs from the second portion 132 of the exhaust fluid 128. In particular, the burner 120 generates a high temperature flame. The high temperature flame causes oxidation of the VOCs. The oxidation of the VOCs results in conversion of the VOCs to H₂O and CO₂. Accordingly, at the burner 120, dangerous VOCs are converted into harmless compounds. In this way, the burner 120 completes removal of the VOCs from the exhaust fluid 128. VOCs are removed from the first portion 130 of the exhaust fluid 128 at the adsorption zone 106 of the VOC concentrator wheel 104. VOCs are removed from the second portion 132 of the exhaust fluid 128 at the burner 120.

In one embodiment, the burner 120 operates at a temperature between 690° C. and 750° C. The burner 120 can operate at other temperatures without departing from the scope of the present disclosure. The temperature of the burner 120 can have an effect on the overall VOC exhaust efficiency of the VOC exhaust system 100.

The purified second portion 132 of the exhaust fluid 128 is passed to the heat exchanger 118 from the burner 120. The heat exchanger 118 takes heat from the purified second portion 132 to the exhaust fluid 128 and heats The second portion 132 of the exhaust fluid 128 coming from the desorption fan 116. This cools the purified second portion 132 of the exhaust fluid 128, though the purified second portion 132 of the exhaust fluid 128 remains quite hot after passing from the heat exchanger 118.

The purified second portion 132 the exhaust fluid 128 is passed from the heat exchanger 118 to the heat exchanger 112. The heat exchanger 112 takes heat from the purified second portion 132 of the exhaust fluid 128 and heats the second portion 132 of the exhaust fluid 128 coming from the cooling zone 108. Accordingly, the temperature imparted to the second portion 132 of the exhaust fluid 128 at the burner 120 is utilized to heat the second portion 132 of the exhaust fluid 128 in preparation to enter the desorption zone 110. As set forth previously, the heat exchanger 112 can heat the second portion 132 of the exhaust fluid 128 to a temperature suitable for desorption of VOCs onto the VOC concentrator wheel 104.

The purified second portion 132 of the exhaust fluid 128 passes from the heat exchanger 112 to the exhaust stack 114. The exhaust stack 114 passes the purified second portion 132 of the exhaust fluid 128 into the atmosphere. In this way, the VOC exhaust system 100 removes VOCs from the exhaust fluid 128 of the semiconductor process 102.

The VOC exhaust system 100 includes a VOC sensor 134 and a VOC sensor 136. The VOC sensor 134 monitors the concentration of VOCs in the exhaust fluid 128 prior to removal of any VOCs by the VOC exhaust system 100. The VOC sensor 136 monitors the concentration of VOCs in the exhaust fluid 128 after removal of VOCs from both the first portion 130 and second portion 132 of the exhaust fluid 128. The VOC sensor 136 may be placed in the exhaust stack 114, outside the exhaust stack 114, or at another location that facilitates measuring the concentration of VOCs in the purified exhaust fluid 128. The VOC sensors 134 and 136 provide VOC concentration signals or data to the control system 126. The control system 126 can calculate an overall VOC exhaust efficiency based on the VOC concentration signals or data from the VOC sensors 134 and 136.

In one embodiment, the VOC sensors 134 and 136 are compound analyzers. The compound analyzers can detect the presence and concentration of selected compounds in a fluid. Accordingly, the compound analyzers can detect the presence and concentration of VOCs in the exhaust fluid 128. In one embodiment, only a single compound analyzer is present. The single compound analyzer can analyze fluid samples from the exhaust fluid 128 at both the inlet to the VOC exhaust system 100 and the outlet to the VOC exhaust system 100.

The temperature sensors 122 and 124 cooperate to measure the temperature of the VOC concentrator wheel 104. The temperature of the VOC concentrator wheel 104 can affect the overall VOC exhaust efficiency of the VOC exhaust system 100. The temperature sensors 122 each generate sensor signals indicative of the temperature of the VOC concentrator wheel 104. The temperature signals from the temperature sensors 122 and 124 can be utilized to determine the temperature of the VOC concentrator wheel 104.

In one embodiment, the temperature sensor 122 is placed at the input side of the adsorption zone 106. The temperature sensor 124 is placed at the output side of the adsorption zone 106. There may be a temperature gradient across the VOC concentrator wheel 104. Accordingly, the temperature signals from the temperature sensors 122 and 124 can be utilized to determine a temperature gradient or average temperature of the VOC concentrator wheel 104. The VOC exhaust system 100 can include additional temperature sensors are positioned to sense the temperature of the VOC concentrator rotor at various locations. All the temperature signals can be provided to the control system 126. In one embodiment, a temperature sensor can be positioned to measure the temperature of the second portion of the exhaust fluid 128 between the heat exchanger 112 and the desorption zone 110.

In some cases, components of the VOC exhaust system 100 may be positioned at locations that can be subject to high temperature fluctuations, air pressure fluctuations, or humidity fluctuations. For example, in some cases, the VOC concentrator wheel 104 may be positioned on a roof of a semiconductor manufacturing facility. In this situation, the time of day, the current weather, and other factors can affect the temperature of the VOC concentrator wheel 104, which in turn can affect the overall VOC exhaust efficiency of the VOC exhaust system 100.

The control system 126 receives data related to various parameters of the VOC exhaust system 100. The control system 126 receives the temperature signals from the temperature sensors 122 and 124. The control system 126 receives the VOC concentration signals from the VOC sensors 134 and 136. The control system 126 receives data indicating the rotational speed of the VOC concentrator wheel 104, the rotational speed of the desorption fan 116, the temperature of the burner 120, and heat transfer parameters of the heat exchangers 112 of 118. Accordingly, the control system 126 is aware of the various current operational parameters of the VOC exhaust system 100.

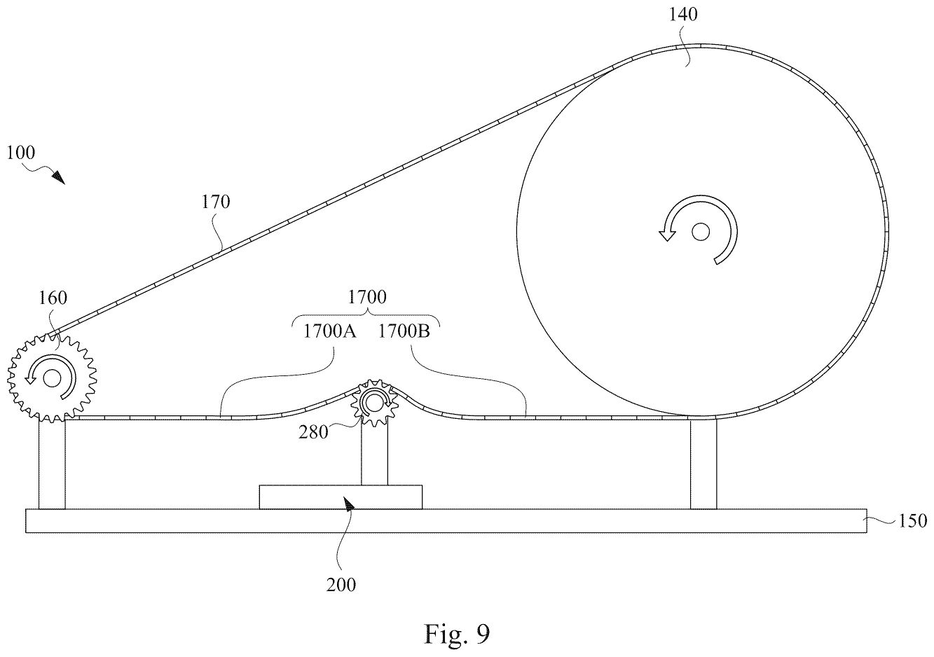

In some embodiments, the control system 126 may a controller and a computer readable storage medium encoded with, i.e., storing, a computer program code, i.e., a set of executable instructions. The controller is electrically coupled to the computer readable storage medium. The controller is configured to execute the computer program code encoded in the computer readable storage medium in order to cause the control system 126 to be used to performing the operations as discussed above with respect to FIG. 9.

In some embodiments, the controller is a central processing unit (CPU), a multi-processor, a distributed processing system, an application specific integrated circuit (ASIC), and/or a suitable processing unit. In some embodiments, the computer readable storage medium includes a semiconductor or solid-state memory, a magnetic tape, a removable computer diskette, a random access memory (RAM), a read-only memory (ROM), a rigid magnetic disk, and/or an optical disk. In some embodiments using optical disks, the computer readable storage medium includes a compact disk-read only memory (CD-ROM), a compact disk-read/write (CD-R/W), and/or a digital video disc (DVD).

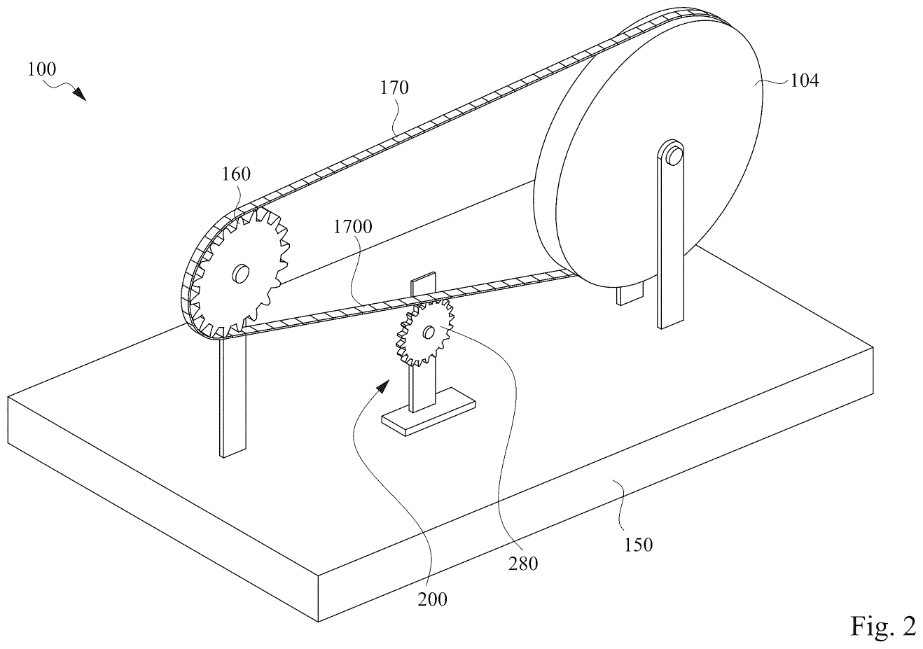

FIG. 2 is a schematic view of a VOC exhaust system, according to some embodiments of the present disclosure. In greater detail, FIG. 2 illustrates a schematic view of the VOC concentrator wheel 104 of the VOC exhaust system 100 as discussed in FIG. 1. The VOC exhaust system 100 includes a supporting platform 150 on which the VOC concentrator wheel 104 is disposed. In some embodiments, the supporting platform 150 can include suitable rigid material, such as steel, or other suitable materials.

The VOC exhaust system 100 further includes a rotor 160 disposed on the supporting platform 150. In some embodiments, the rotor 160 may include a motor which can be actuated to rotate the rotor 160. The VOC exhaust system 100 further includes a traction chain 170 mechanically couples the VOC concentrator wheel 104 and the rotor 160 with each other. For example, the teeth of the rotor 160 and the teeth of the VOC concentrator wheel 104 may be mechanically engaged to the traction chain 170. Accordingly, during the VOC exhaust process as discussed in FIG. 1, the VOC concentrator wheel 104 can be rotated by actuating the rotor 160, and the traction chain 170 coupled to the rotor 160 can enable the rotation of the VOC concentrator wheel 104.

The VOC exhaust system 100 further includes a chain adjustment tool 200 disposed on the disposed on the supporting platform 150. In some embodiments, the chain adjustment tool 200 may include a gear 280 engaged to a portion 1700 of the traction chain 170. Here, the portion 1700 may be referred to a portion of the traction chain 170 that extends from the bottom side of the rotor 160 to the bottom side of the VOC concentrator wheel 104. In some embodiments, the gear 280 of the chain adjustment tool 200 supports the portion 1700 of the traction chain 170 from the bottom side of the portion 1700 of the traction chain 170, and may be able to adjust the position of the portion 1700 of the traction chain 170, which will be discussed in more detail later.

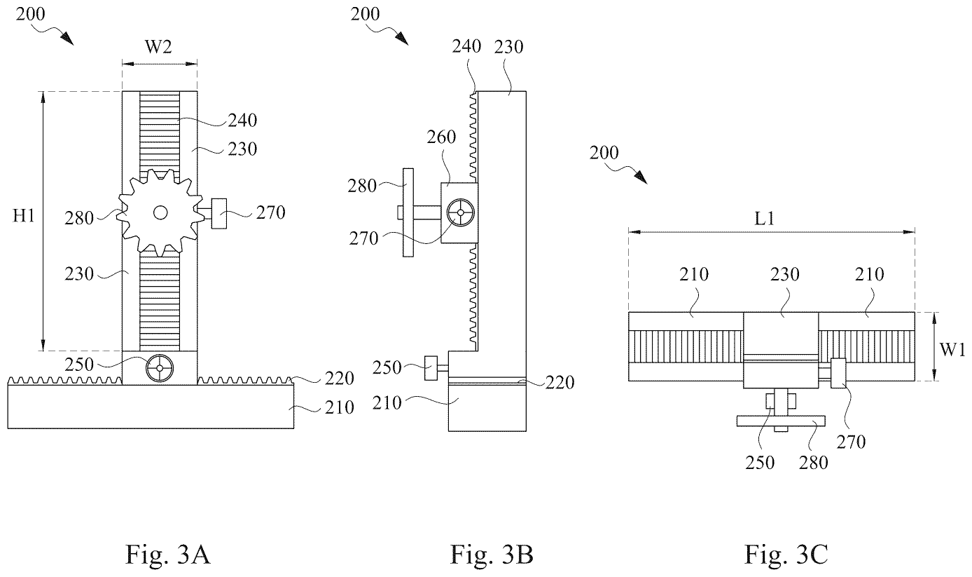

FIGS. 3A, 3B, and 3C are schematic views of a chain adjustment tool of a VOC exhaust system, according to some embodiments of the present disclosure. In greater detail, FIGS. 3A, 3B, 3C are schematic views of the chain adjustment tool 200 as discussed in FIG. 2, in which FIG. 3A is a front view of the chain adjustment tool 200, FIG. 3B is a side view of the chain adjustment tool 200, and FIG. 3C is a top view of the chain adjustment tool 200, respectively. The chain adjustment tool 200 includes a base 210, a slide rail 220 on the base 210, a slider 230 coupled to the slide rail 220, a slide rail 240 on the slider 230, a slider 260 coupled to the slide rail 240, and a gear 280 coupled to the slider 260. In some embodiments, the base 210 can be made of a rigid material, such as steel. The base 210 can be fixed on the supporting platform 150 (see FIG. 2) using suitable method, such as by screws in some embodiments.

The slider 230 is movable along the slide rail 220. In some embodiments, the slider 230 can be moved using a handle wheel 250 mechanically connecting the slider 230 and the slide rail 220. For example, by rotating the handle wheel 250, the slider 230 can be moved, back and forth, along the slide rail 220 in a horizontal direction. Similarly, the slider 260 is movable along the slide rail 240 on the slider 230. In some embodiments, the slider 260 can be moved using a handle wheel 270 mechanically connecting the slider 260 and the slide rail 240. For example, by rotating the handle wheel 270, the slider 260 can be moved, up and down, along the slide rail 240 in a vertical direction. In some embodiments, the slide rail 220 and the slide rail 240 may be gear racks or other suitable types of slide rails. In some embodiments, the handle wheels 250 and 270 can be rotated manually by a user, or can be rotated automatically through a control system (e.g., the control system 126 in FIG. 1).

The gear 280 is fixed on the slider 260 and is rotatable for supporting the traction chain 170 (see FIG. 2) during the movement of the traction chain 170. Moreover, based on the above discussion, the position of the gear 280 is adjustable. For example, the gear 280 can be moved along the horizontal direction by moving the slider 230 along the slide rail 220. On the other hand, the gear 280 can be moved along the vertical direction by moving the slider 260 along the slide rail 240 on the slider 230. This configuration allows the gear 280 to be movable at least along two directions, and may be beneficial to adjust the position of the traction chain 170 of the VOC exhaust system 100, which will be discussed in more detail later.

The base 210 may include a length L1 and a width W1. In some embodiments, the length L1 is in a range from about 280 mm to about 320 mm, such as 300 mm. The width W1 is in a range from about 60 mm to about 100 mm, such as 80 mm. The slider 230 may include a width W2, and the slide rail 240 on the slider 230 may include a height H1. In some embodiments, the height H1 is in a range from about 280 mm to about 320 mm, such as 300 mm. The width W2 is in a range from about 60 mm to about 100 mm, such as 80 mm.

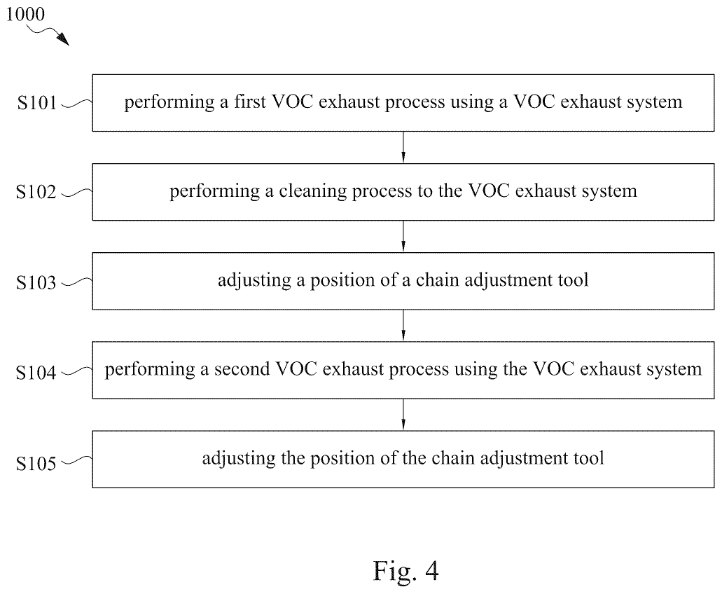

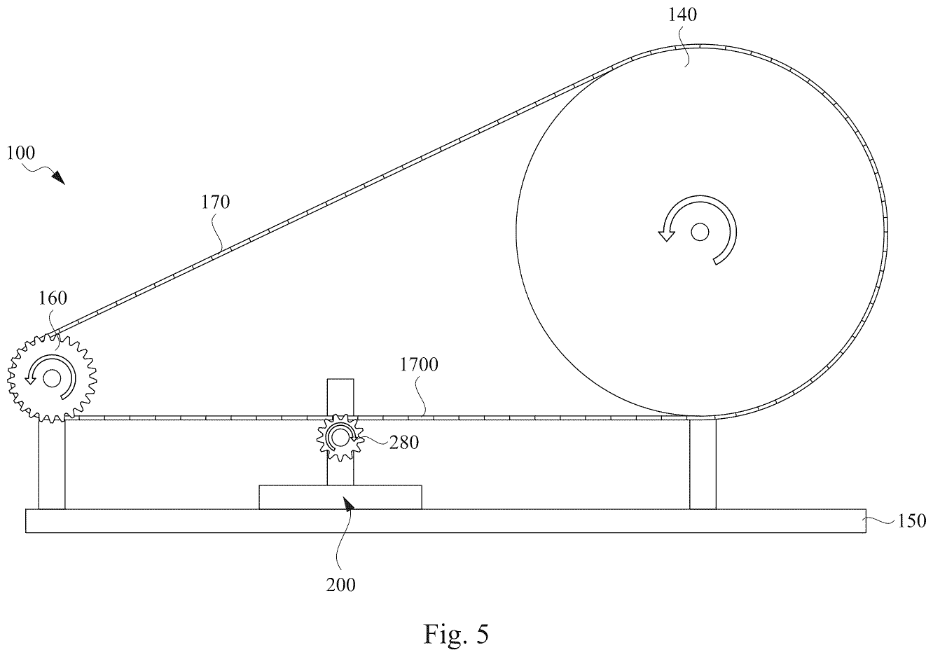

FIG. 4 is a method of operating a VOC exhaust system in accordance with some embodiments. FIGS. 5 to 9 are schematic views of a VOC exhaust system at various stages of operating a VOC exhaust system accordance with some embodiments. A method 1000 is provided, and the method 1000 of FIG. 4 will be discussed in conjunction with FIGS. 5 to 9. Although the method 1000 is described as a series of acts, it will be appreciated that these acts are not limiting in that the order of the acts can be altered in other embodiments. In other embodiments, some acts that are illustrated and/or described may be omitted in whole or in part.

Reference is made to FIGS. 4 and 5. The method 1000 starts from operation S101 by performing a first VOC exhaust process using a VOC exhaust system. For example, as shown in FIG. 5, a first VOC exhaust process is performed using the VOC exhaust system 100. During the first VOC exhaust process, the VOC concentrator wheel 104 is rotated by actuating the rotor 160, and the traction chain 170 coupled to the rotor 160 and the VOC concentrator wheel 104 may enable the rotation of the VOC concentrator wheel 104. During the rotation of the VOC concentrator wheel 104, the gear 280 of the chain adjustment tool 200 is also rotated along the portion 1700 of the traction chain 170. In some embodiments, the rotation direction of the gear 280 of the chain adjustment tool 200 may be opposite to the rotation direction of the VOC concentrator wheel 104 and the rotor 160. For example, when the VOC concentrator wheel 104 and the rotor 160 rotate counter clockwise, the gear 280 of the chain adjustment tool 200 may rotate clockwise, and vice versa.

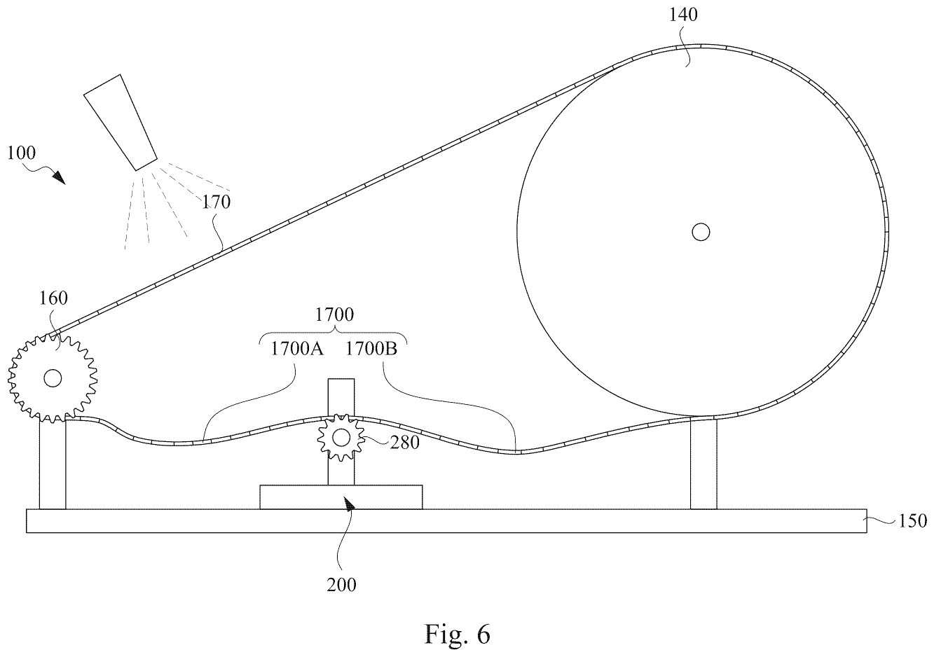

Reference is made to FIGS. 4 and 6. The method 1000 proceeds to operation S102 by performing a cleaning process to the VOC exhaust system. After a long period of performing the VOC exhaust process, the VOC concentrator wheel 104 of the VOC exhaust system 100 need to be cleaned, for example, every six months, to ensure the absorption capability of the VOC concentrator wheel 104. In some embodiments, the cleaning process can be a high pressure water-jet cleaning. For example, contamination, such as particles, dusts, etc., can be removed from the VOC concentrator wheel 104 through high pressure water-jet. In some embodiments, the cleaning process may be performed during the VOC exhaust process of operation S101.

However, during the cleaning process, water may fall on the VOC concentrator wheel 104 and/or the traction chain 170, and may result an increasing weight of the VOC concentrator wheel 104 and/or the traction chain 170. In some embodiments, due to the increasing weight of the VOC concentrator wheel 104 and/or the traction chain 170, the traction chain 170 may bear an even higher stress when pulling the VOC concentrator wheel 104, which may resulting in an irreversibly or temporarily deformation of the traction chain 170. For example, after the cleaning process is complete, and the traction chain 170 may be loosened due to the increasing weight of the traction chain 170 and/or performing the VOC exhaust process again.

As shown in FIG. 6, the portion 1700 of the traction chain 170 may include a first segment 1700A and a second segment 1700B, in which the first segment 1700A is a segment of the portion 1700 of the traction chain 170 between the rotor 160 and the gear 280 of the chain adjustment tool 200, and the second segment 1700B is a segment of the portion 1700 of the traction chain 170 between the VOC concentrator wheel 104 and the gear 280 of the chain adjustment tool 200. As mentioned above, due to the deformation of the traction chain 170, bottom ends of the first segment 1700A and the second segment 1700B of the traction chain 170 may drop downwardly. The loosened traction chain 170 may skid easily over the VOC concentrator wheel 104, and the VOC exhaust efficiency of organic waste gas and the service life of the VOC exhaust system 100 will be affected.

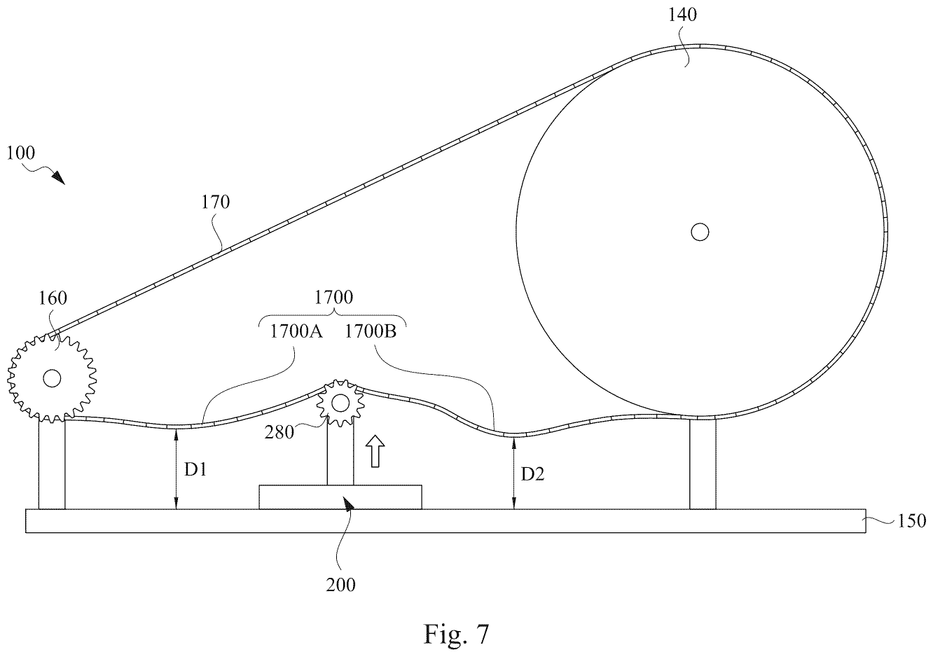

Reference is made to FIGS. 4, 7, and 8. The method 1000 proceeds to operation S103 by adjusting a position of a chain adjustment tool. As shown in FIG. 7, the gear 280 of the chain adjustment tool 200 is moved upwardly in a vertical direction, so as to push the portion 1700 of the traction chain 170 upwardly and to tighten the traction chain 170. Accordingly, it can be seen that the bottom ends of the first segment 1700A and the second segment 1700B of the traction chain 170 are pushed upwardly. The movement of the gear 280 along the vertical direction has been discussed above with respect to FIGS. 3A to 3C, and thus relevant details will not be repeated for brevity.

However, although in FIG. 7 the bottom ends of the first segment 1700A and the second segment 1700B of the traction chain 170 are pushed upwardly, the bottom ends of the first segment 1700A and the second segment 1700B are at different levels. For example, the bottom end of the first segment 1700A is higher than the bottom end of the second segment 1700B. That is, a vertical distance D1 between the bottom end of the first segment 1700A and the supporting platform 150 is greater than a vertical distance D2 between the bottom end of the second segment 1700B and the supporting platform 150.

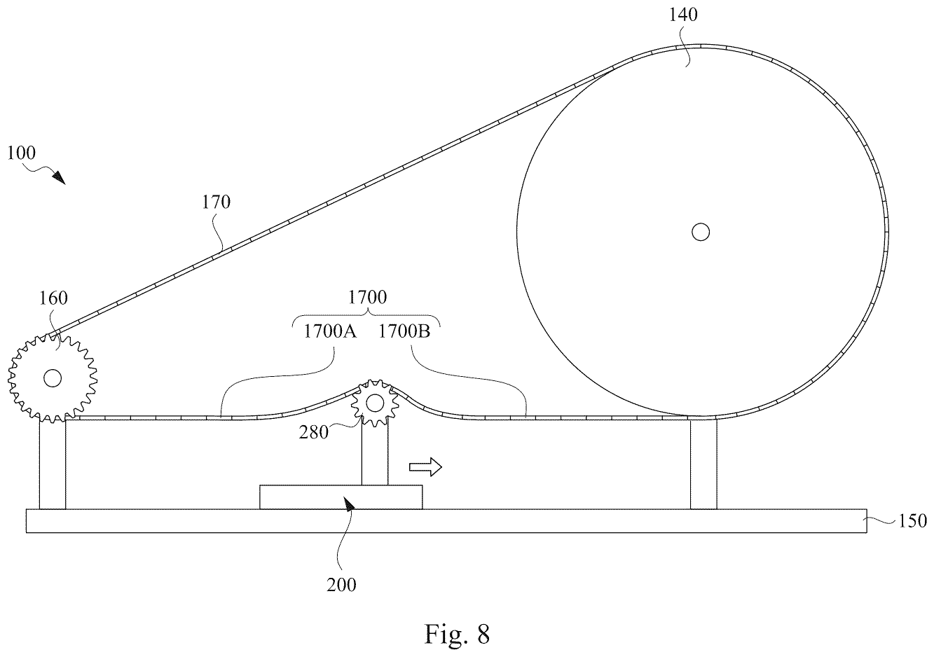

Accordingly, as shown in FIG. 8, the gear 280 of the chain adjustment tool 200 can be further moved, in a horizontal direction, toward the bottom end of the second segment 1700B of the traction chain 170, such that the bottom end of the second segment 1700B of the traction chain 170 is pushed upwardly, and thus the bottom end of the first segment 1700A is at a substantially same level as the bottom end of the second segment 1700B.

Reference is made to FIGS. 4 and 9. The method 1000 proceeds to operation S104 by performing a second VOC exhaust process using the VOC exhaust system. After the traction chain 170 is tightened, another VOC exhaust process can be performed using the VOC exhaust system 100 as discussed in FIG. 1. Because of the tightened traction chain 170, the traction chain 170 may not skid over the VOC concentrator wheel 104 and/or the rotor 160 easily, and thus the VOC exhaust efficiency of the VOC exhaust system 100 can be maintained, and the life time of the VOC exhaust system 100 can also be extended.

Reference is made to FIG. 4. The method 1000 proceeds to operation S105 by adjusting the position of the chain adjustment tool. As mentioned above with respect to operation S102, the traction chain 170 may be loosened due the cleaning process is complete. In operation S103, the loosened traction chain 170 is tightened using the chain adjustment tool 200. However, the deformation of the traction chain 170 may be temporary. For example, if the water dropped on the traction chain 170 evaporates after a period of time (e.g., during the operation S104), the weight of the dry traction chain 170 may be reduced, and the traction chain 170 may be tightened back slightly. Accordingly, the chain adjustment tool 200 can be adjusted again to loosen the traction chain 170.

The traction chain 170 can be loosened again by moving the gear 280 of the chain adjustment tool 200. In some embodiments, the gear 280 can be moved along a direction that is opposite to the direction for moving the gear 280 in operation S103. For example, along the vertical direction, when the gear 280 is moved along a first direction (e.g., upwardly) in operation S103, the gear 280 can be moved along a second direction (e.g., downwardly) opposite to the first direction in operation S105. Similarly, along the horizontal direction, when the gear 280 is moved along a first direction (e.g., toward the second segment 1700B of the traction chain 170) in operation S103, the gear 280 can be moved along a second direction (e.g., toward the first segment 1700A of the traction chain 170) opposite to the first direction in operation S105.

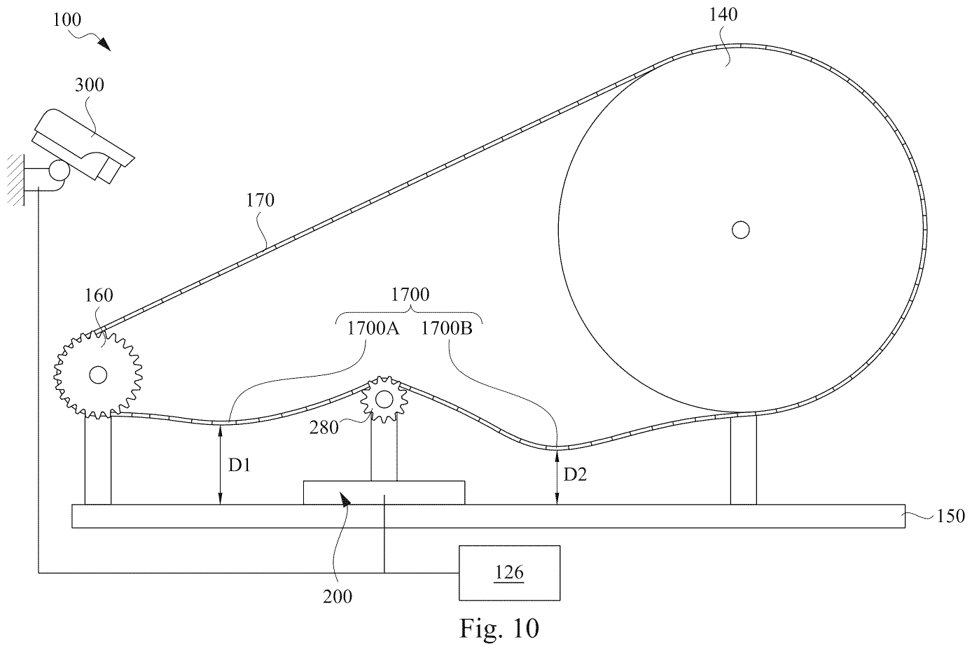

FIG. 10 is a schematic view of a VOC exhaust system, according to some embodiments of the present disclosure. It is noted that some elements of the VOC exhaust system of FIG. 10 may be similar to those described above, such elements are labeled the same and relevant details will not be repeated for brevity.

The VOC exhaust system further includes an image sensor 300 that is communicated, either by wires or wireless, with the control system 126. The image sensor 300 can capture an image of the portion 1700 of the traction chain 170, and the captured image is sent to the control system 126. The control system 126 can calculate the positions of the bottom ends of the first segment 1700A and the second segment 1700B of the traction chain 170, respectively, based on the captured image. In some embodiments, the image sensor 300 can capture the image of the traction chain 170 after the cleaning process (e.g., operation S103 of FIG. 4) is complete.

The control system 126 can also determine whether the condition of the traction chain 170 is acceptable. In some embodiments, determine whether the condition of the traction chain 170 is acceptable can include a first determination process and a second determination process.

In the first determination process, if the bottom end of the first segment 1700A of the traction chain 170 and/or the bottom end of the second segment 1700B of the traction chain 170 is below a predetermined level, the condition of the traction chain 170 is determined as unacceptable. That is, if the vertical distance D1 between the bottom end of the first segment 1700A and the supporting platform 150 and/or a vertical distance D2 between the bottom end of the second segment 1700B and the supporting platform 150 are below a predetermined value, the condition of the traction chain 170 is determined as unacceptable. In such condition, the traction chain 170 may be too loose and may affect the VOC exhaust efficiency of the VOC exhaust system 100.

On the other hand, the condition of the traction chain 170 is determined as acceptable when the bottom end of the first segment 1700A of the traction chain 170 and the bottom end of the second segment 1700B of the traction chain 170 are both above the predetermined level. That is, if the vertical distance D1 and the vertical distance D2 both exceeds the predetermined value, the condition of the traction chain 170 is determined as acceptable.

In the second determination process, if the bottom end of the first segment 1700A of the traction chain 170 and the bottom end of the second segment 1700B of the traction chain 170 are not at a same level, the condition of the traction chain 170 is determined as unacceptable. In other embodiments, if the level difference between the bottom end of the first segment 1700A of the traction chain 170 and the bottom end of the second segment 1700B of the traction chain 170 exceeds a predetermined value, the condition of the traction chain 170 is determined as unacceptable. That is, if the difference between vertical distance D1 and the vertical distance D2 is beyond a predetermined value, the condition of the traction chain 170 is determined as unacceptable.

On the other hand, the condition of the traction chain 170 is determined as acceptable when the bottom end of the first segment 1700A of the traction chain 170 and the bottom end of the second segment 1700B of the traction chain 170 are at a same level. That is, if the vertical distance D1 and the vertical distance D2 are substantially the same, the condition of the traction chain 170 is determined as acceptable.

The first determination process and the second determination process can be performed prior to the operation S103 as discussed in FIG. 4. In some embodiments, the determination process can be performed prior to or after the second determination process. If the traction chain 170 passes the first determination process and the second determination process, the operation S103 as discussed in FIG. 4 can be skipped. That is, the condition of the traction chain 170 is acceptable.

If the traction chain 170 does not pass the first determination process and the second determination process, the traction chain 170 can be adjusted during the operation S103 as discussed in FIG. 4. That is, when the condition of the traction chain 170 is unacceptable, the traction chain 170 is going to be adjusted.

With respect to the first determination process, if the bottom end of the first segment 1700A of the traction chain 170 and/or the bottom end of the second segment 1700B of the traction chain 170 is below a predetermined level. The traction chain 170 can be adjusted by moving the gear 280 in a vertical direction, such as upwardly, to tighten the traction chain 170.

With respect to the second determination process, if the bottom end of the first segment 1700A of the traction chain 170 and the bottom end of the second segment 1700B of the traction chain 170 are not at a same level, the traction chain 170 can be adjusted by moving the gear 280 in a horizontal direction, to adjust the bottom end of the first segment 1700A and the bottom end of the second segment 1700B to a same level. In some embodiments, if the bottom end of the first segment 1700A is lower than the bottom end of the second segment 1700B, the traction chain 170 can be adjusted by moving the gear 280 toward the first segment 1700A until the bottom end of the first segment 1700A and the bottom end of the second segment 1700B are at a same level. Similarly, if the bottom end of the second segment 1700B is lower than the bottom end of the first segment 1700A, the traction chain 170 can be adjusted by moving the gear 280 toward the second segment 1700B until the bottom end of the first segment 1700A and the bottom end of the second segment 1700B are at a same level.

In some embodiments, the chain adjustment tool 200 can be communicated with the control system 126. The control system 126 can performed the calculation of the first and second determination processes as discussed above, and can also control the chain adjustment tool 200 to adjust the traction chain 170. In greater detail, the control system 126 may be able to control all elements of the chain adjustment tool 200 as discussed in FIGS. 3A to 3C, to obtain an automatically control of the position of the gear 280 of the chain adjustment tool 200.

According to the aforementioned embodiments, it can be seen that the present disclosure offers advantages in fabricating integrated circuits. It is understood, however, that other embodiments may offer additional advantages, and not all advantages are necessarily disclosed herein, and that no particular advantage is required for all embodiments. Embodiments of the present disclosure utilize a chain adjustment tool to adjust a traction chain of the VOC exhaust system to maintain a high VOC exhaust efficiency. In particular, the chain adjustment tool includes a gear that can be moved, up and down or back and forth, to adjust the traction chain with double insurance of anti-slip. This may provide advantages to the VOC exhaust system. For example, the traction chain can be tightened using the chain adjustment tool to avoid the traction chain from skidding over the VOC concentrator wheel or slipping from the VOC concentrator wheel. Moreover, the chain adjustment tool can be installed in the VOC exhaust system easily without stopping the machine. With such configuration, the lift time of the VOC exhaust system can be extended, and the replacement cost of the VOC exhaust system can also be reduced.

In some embodiments of the present disclosure, a method includes performing a volatile organic compound (VOC) exhaust process by rotating a concentrator wheel through a rotor, the concentrator wheel being mechanically coupled to the rotor through a traction chain; performing a cleaning process to the concentrator wheel and the traction chain; and after performing the cleaning process, tightening the traction chain by pushing the traction chain upwardly through a chain adjustment tool coupled to a bottom side of the traction chain.

In some embodiments, the chain adjustment tool comprises a gear engaged with the traction chain.

In some embodiments, the method further includes moving the gear of the chain adjustment tool along a horizontal direction.

In some embodiments, prior to moving the gear of the chain adjustment tool, the traction chain comprises a first segment on one side of the gear and a second segment on another side of the gear, a bottom end of the first segment being lower than a bottom end of the second segment, and wherein moving the gear of the chain adjustment tool comprises moving the gear of the chain adjustment tool toward the first segment of the traction chain.

In some embodiments, moving the gear of the chain adjustment tool is performed until the bottom end of the first segment and the bottom end of the second segment are substantially at a same level.

In some embodiments, the method further includes performing another VOC exhaust process after tightening the traction chain.

In some embodiments, moving the chain adjustment tool downwardly to loosen the traction chain after performing the another VOC exhaust process.

In some embodiments, the traction chain is loosened as a result of the cleaning process.

In some embodiments of the present disclosure, a method includes performing a volatile organic compound (VOC) exhaust process using a VOC exhaust system, the VOC exhaust system comprises a concentrator wheel, a rotor, a traction chain mechanically coupling the concentrator wheel and the rotor, and a chain adjustment tool having a gear coupled to a bottom side of the traction chain, wherein the traction chain comprises a first segment on one side of the gear and a second segment on another side of the gear; performing a cleaning process to the VOC exhaust system; and moving the gear of the chain adjustment tool along a horizontal direction until a bottom end of the first segment and a bottom end of the second segment are substantially at a same level.

In some embodiments, prior to moving the gear of the chain adjustment tool, the bottom end of the first segment is lower than the bottom end of the second segment, and wherein moving the gear of the chain adjustment tool comprises moving the gear of the chain adjustment tool toward the first segment of the traction chain.

In some embodiments, the chain adjustment tool comprises a slide rail extending along the horizontal direction, and a slider coupled to the slide rail, the gear being connected to the slider, wherein moving the gear of the chain adjustment tool comprises moving the slider along the slide rail.

In some embodiments, the method further includes moving the gear of the chain adjustment tool along a vertical direction to push the traction chain upwardly.

In some embodiments, the chain adjustment tool comprises a slide rail extending along the vertical direction, and a slider coupled to the slide rail, the gear being connected to the slider, wherein moving the gear of the chain adjustment tool comprises moving the slider along the slide rail.

In some embodiments, moving the gear along the vertical direction is performed prior to moving the gear of the chain adjustment tool along the horizontal direction.

In some embodiments, moving the gear along the vertical direction is performed after moving the gear of the chain adjustment tool along the horizontal direction.

In some embodiments of the present disclosure, a system includes a concentrator wheel. A rotor is configured to rotate concentrator wheel. A traction chain mechanically couples the concentrator wheel and the rotor. A chain adjustment tool is coupled to the traction chain and comprising a gear engaged with the traction chain, wherein the gear is movable along a horizontal direction and a vertical direction.

In some embodiments, the chain adjustment tool comprises a first slide rail extending along the horizontal direction, a first slider coupled to the first slide rail, the first slider being movable along the first slide rail, a second slide rail on the first slider and extending along the vertical direction, and a second slider coupled to the second slide rail, the second slider being movable along the second slide rail, wherein the gear is connected to the second slider.

In some embodiments, the chain adjustment tool further comprises a first handle wheel coupled to the first slider and configured to adjust a position of the first slider along the first slide rail, and a second handle wheel coupled to the second slider and configured to adjust a position of the second slider along the second slide rail.

In some embodiments, the gear is engaged with the traction chain from a bottom side of the traction chain.

In some embodiments, the gear is engaged with a portion of the traction chain extending from a bottom side of the rotor to a bottom side of the concentrator wheel.

In some embodiments, the concentrator wheel, the rotor, and the chain adjustment tool are disposed on a platform.

In some embodiments of the present disclosure, a system includes a concentrator wheel. A rotor is configured to rotate concentrator wheel. A traction chain mechanically couples the concentrator wheel and the rotor. A chain adjustment tool is coupled to the traction chain, wherein the chain adjustment tool is configured to move the traction chain upwardly or downwardly.

In some embodiments, the chain adjustment tool comprises a gear engaged with the traction chain.

In some embodiments, the chain adjustment tool comprises a first slide rail extending along the horizontal direction, a first slider coupled to the first slide rail, the first slider being movable along the first slide rail, a second slide rail on the first slider and extending along the vertical direction, and a second slider coupled to the second slide rail, the second slider being movable along the second slide rail, wherein the gear is connected to the second slider.

In some embodiments, the chain adjustment tool further comprises a first handle wheel coupled to the first slider and configured to adjust a position of the first slider along the first slide rail, and a second handle wheel coupled to the second slider and configured to adjust a position of the second slider along the second slide rail.

In some embodiments, the chain adjustment tool is coupled to a bottom side of the traction chain.

In some embodiments, the chain adjustment tool is coupled to a portion of the traction chain extending from a bottom side of the rotor to a bottom side of the concentrator wheel.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
performing a volatile organic compound (VOC) exhaust process by rotating a concentrator wheel through a rotor, the concentrator wheel being mechanically coupled to the rotor through a traction chain;
performing a cleaning process to the concentrator wheel and the traction chain; and
after performing the cleaning process, tightening the traction chain by pushing the traction chain upwardly through a chain adjustment tool coupled to a bottom side of the traction chain.

2. The method of claim 1, wherein the chain adjustment tool comprises a gear engaged with the traction chain.

3. The method of claim 2, further comprising moving the gear of the chain adjustment tool along a horizontal direction.

4. The method of claim 3, wherein prior to moving the gear of the chain adjustment tool, the traction chain comprises a first segment on one side of the gear and a second segment on another side of the gear, a bottom end of the first segment being lower than a bottom end of the second segment, and wherein moving the gear of the chain adjustment tool comprises moving the gear of the chain adjustment tool toward the first segment of the traction chain.

5. The method of claim 4, wherein moving the gear of the chain adjustment tool is performed until the bottom end of the first segment and the bottom end of the second segment are substantially at a same level.

6. The method of claim 1, further comprising performing another VOC exhaust process after tightening the traction chain.

7. The method of claim 6, further comprising moving the chain adjustment tool downwardly to loosen the traction chain after performing the another VOC exhaust process.

8. The method of claim 1, wherein the traction chain is loosened as a result of the cleaning process.

9. A system, comprising:
a concentrator wheel;
a rotor configured to rotate concentrator wheel;
a traction chain mechanically coupling the concentrator wheel and the rotor; and
a chain adjustment tool coupled to the traction chain and comprising a gear engaged with the traction chain, wherein the gear is movable along a horizontal direction and a vertical direction.

10. The system of claim 9, wherein the chain adjustment tool comprises:
a first slide rail extending along the horizontal direction;
a first slider coupled to the first slide rail, the first slider being movable along the first slide rail;
a second slide rail on the first slider and extending along the vertical direction; and
a second slider coupled to the second slide rail, the second slider being movable along the second slide rail, wherein the gear is connected to the second slider.

11. The system of claim 10, wherein the chain adjustment tool further comprises:
a first handle wheel coupled to the first slider and configured to adjust a position of the first slider along the first slide rail; and
a second handle wheel coupled to the second slider and configured to adjust a position of the second slider along the second slide rail.

12. The system of claim 9, wherein the gear is engaged with the traction chain from a bottom side of the traction chain.

13. The system of claim 9, wherein the gear is engaged with a portion of the traction chain extending from a bottom side of the rotor to a bottom side of the concentrator wheel.

14. The system of claim 9, wherein the concentrator wheel, the rotor, and the chain adjustment tool are disposed on a platform.

15. A system, comprising:
a concentrator wheel;
a rotor configured to rotate concentrator wheel;
a traction chain mechanically coupling the concentrator wheel and the rotor; and
a chain adjustment tool coupled to the traction chain, wherein the chain adjustment tool is configured to move the traction chain upwardly or downwardly.

16. The system of claim 15, wherein the chain adjustment tool comprises a gear engaged with the traction chain.

17. The system of claim 16, wherein the chain adjustment tool comprises:
a first slide rail extending along a horizontal direction;
a first slider coupled to the first slide rail, the first slider being movable along the first slide rail;
a second slide rail on the first slider and extending along a vertical direction; and
a second slider coupled to the second slide rail, the second slider being movable along the second slide rail, wherein the gear is connected to the second slider.

18. The system of claim 17, wherein the chain adjustment tool further comprises:
a first handle wheel coupled to the first slider and configured to adjust a position of the first slider along the first slide rail; and
a second handle wheel coupled to the second slider and configured to adjust a position of the second slider along the second slide rail.

19. The system of claim 15, wherein the chain adjustment tool is coupled to a bottom side of the traction chain.

20. The system of claim 15, wherein the chain adjustment tool is coupled to a portion of the traction chain extending from a bottom side of the rotor to a bottom side of the concentrator wheel.
